(19) United States
(12) Patent Application Publication
(10) Pub. No.: US 2012/0048367 A1
(43) Pub. Date: Mar. 1, 2012

(54) LIGHT SCATTERING INORGANIC SUBSTRATES

(76) Inventors: Andrey Kobyakov, Painted Post, NY (US); Aramais Zakharian, Painted Post, NY (US)

(21) Appl. No.: 13/212,703

(22) Filed: Aug. 18, 2011

Related U.S. Application Data
(60) Provisional application No. 61/376,374, filed on Aug. 24, 2010.

(51) Int. Cl. H01L 31/0236; G02B 5/02

(52) U.S. Cl. 136/256; 359/599

(57) ABSTRACT

Light scattering inorganic substrates having an inorganic sheet having composite features distributed on a surface of the inorganic sheet, wherein the composite features each have at least a first and a second size scale. The first size scale enhances light absorption at wavelengths in the range of from 350 nm to 600 nm, and the second size scale enhances light absorption at wavelengths in the range of from 600 nm to 1100 nm. The substrates are, useful, for example, for photovoltaic devices.

This application claims the benefit of priority under 35 U.S.C. §119 of the U.S. Provisional Application Ser. No. 61/376,374 filed on Aug. 24, 2010 the content of which is relied upon and incorporated herein by reference in its entirety.

### BACKGROUND

1. Field

Embodiments relate generally to light scattering inorganic substrates and more particularly to light scattering inorganic substrates comprising hemispherical particles with various size distributions useful for, for example, photovoltaic cells.

2. Technical Background

For thin-film silicon photovoltaic solar cells, light must be effectively coupled into the silicon layer and subsequently trapped in the layer to provide sufficient path length for light absorption. A path length greater than the thickness of the silicon is especially advantageous at longer wavelengths where the silicon absorption length is typically tens to hundreds of microns. Light is typically incident from the side of the deposition substrate such that the substrate becomes a superstrate in the cell configuration. A typical tandem cell incorporating both amorphous and microcrystalline silicon typically has a substrate having a transparent electrode deposited thereon, a top cell of amorphous silicon, a bottom cell of microcrystalline silicon, and a back contact or counter electrode.

Amorphous silicon absorbs primarily in the visible portion of the spectrum below 700 nanometers (nm) while microcrystalline silicon absorbs similarly to bulk crystalline silicon with a gradual reduction in absorption extending to ˜1200 nm. Both types of material may benefit from textured surfaces. Depending on the size scale of the texture, the texture may perform light trapping and/or reduce Fresnel loss at the Si/substrate interface.

It would be advantageous to have light scattering inorganic substrates wherein composite features having at least two size scales, for example, at least two size scales of hemispherical particles create a textured surface on the substrate. Further, it would be advantageous to have a textured substrate with an enhanced scattering at all wavelengths, for example, 350 nm to 1100 nm.

### SUMMARY

Light scattering inorganic substrates, as described herein, address one or more of the above-mentioned disadvantages of conventional light scattering inorganic substrates and may provide one or more of the following advantages: enhanced light trapping or light absorption at several wavelengths, and several methods can be used to make the substrates. Also, inorganic substrates using composite features having a combination of particle sizes, textures on the particles, spatial particle density, and/or a combination of particle sizes with textures may also enhance light scattering across all wavelengths, for example, 350 nm to 1100 nm.

One embodiment is a light scattering inorganic substrate comprising an inorganic sheet having composite features distributed on a surface of the inorganic sheet, wherein the composite features each comprise at least a first and a second size scale, wherein the first size scale enhances light absorption at wavelengths in the range of from 350 nm to 600 nm, and wherein the second size scale enhances light absorption at wavelengths in the range of from 600 nm to 1100 nm.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 is a yz-cross-section of a conventional a-Si photovoltaic cell using a non-textured flat glass substrate.

FIG. 2 is a cross-section of a unit lattice-element of a periodic a-Si cell based on a light scattering inorganic substrate comprising a combination of large (d=1 μm) and small (d=200 nm) diameter hemispherical glass particles on a planar glass sheet, according to one embodiment.

FIGS. 3A and 3B show optical constants of the thin-film silicon cell materials used in the simulations.

FIG. 4 shows the absorption efficiency computed for a conventional a-Si cell based on a flat glass substrate and for light scattering inorganic substrate based cells with mono-disperse distributions of d=200 nm-2000 nm diameter hemispherical particles.

FIG. 5 shows the absorption efficiency computed for a conventional a-Si cell based on a flat glass substrate and for light scattering inorganic substrate based cells with combined periodic distributions of d=200 nm and 1000 nm diameter hemispherical particles.

FIG. 6 shows absorption efficiency computed for a conventional a-Si cell based on a flat glass substrate and for light scattering inorganic substrate based cells with periodic distributions of smooth hemispherical particles at the glass/TCO interface and rough TCO/a-Si interface.

FIG. 7 shows the absorption efficiency dependence on the wavelength computed for a tandem cell, according to one embodiment.

FIG. 8 is a cross-section of a unit lattice-element of a periodic Si-tandem cell based on a light scattering inorganic substrate comprising a combination of large diameter glass particles; and convex areas distributed on the surface of the particles, on a planar glass sheet, according to one embodiment.

FIG. 9 is a cross-section of a unit lattice-element of a periodic Si-tandem cell based on a light scattering inorganic substrate comprising a combination of large diameter glass particles; and concave areas distributed on the surface of the particles, on a planar glass sheet, according to one embodiment.

FIG. 10 is a graph of the comparison of absorption efficiency of silicon tandem cells deposited on a light scattering inorganic substrate comprising hemispherical bumps of diameter d=2500 nm and height 800 nm, arranged on a hexagonal lattice, and of the same type of substrate but with additional texture formed by smaller size d=500 nm etched (concave) hemispherical features.

FIG. 11 is an illustration of features of a photovoltaic device, according to one embodiment.

### DETAILED DESCRIPTION

Reference will now be made in detail to various embodiments of the invention, examples of which are illustrated in the accompanying drawings. Wherever possible, the same reference numbers will be used throughout the drawings to refer to the same or like parts.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module.

As used herein, the term “adjacent” can be defined as being in close proximity. Adjacent structures may or may not be in physical contact with each other. Adjacent structures can have other layers and/or structures disposed between them.

As used herein, the term “conformal” can be defined as defining a morphologically uneven interface with another body and having a thickness that is the same everywhere along the interface. This is undoubtedly an idealization and may be used for abstract or theoretical purposes. Real films will exhibit thickness variations along edges, steps or other elements of the morphology of the interface but yet be considered conformal films depending on the magnitude of the thickness variations.

One embodiment is a light scattering inorganic substrate comprising an inorganic sheet having composite features distributed on a surface of the inorganic sheet, wherein the composite features each comprise at least a first and a second size scale, wherein the first size scale enhances light absorption at wavelengths in the range of from 350 nm to 600 nm, and wherein the second size scale enhances light absorption at wavelengths in the range of from 600 nm to 1100 nm.

The composite features can be made by depositing particles on a substrate by methods known in the art such as self-assembly, dip coating, adhesively bonding particles, or pressing particles into a softened substrate.

According to one embodiment, the second size scale is in the range of from greater than 600 nm to 8 microns. The second size scale range can be a range of average diameters of particles.

According to one embodiment, the first size scale is in the range of from 600 nm or less, for example, 1 nm to 600 nm. The first size scale range can be a range of average diameters of particles.

In one embodiment, the composite features are distributed in a monolayer.

The composite features can be distributed in a pattern, for example, a square lattice pattern or a hexagonal pattern.

In one embodiment, the composite features each comprise an inorganic particle having the second size scale; and concave areas distributed on a surface of the particle and having the first size scale.

In one embodiment, the composite features each comprise an inorganic particle having the second size scale; and convex areas distributed on a surface of the particle and having the first size scale.

According to some embodiments, the particles are spherical and a portion of each of the particles protrudes from the surface. For example, each particle can protrude from the surface at a height of from the particle diameter divided by 4 to a height of the particle diameter divided by 2.

One embodiment is a light scattering inorganic substrate comprising a planar inorganic sheet comprising a surface comprising hemispherical inorganic particles distributed on the surface, wherein the hemispherical particles comprise at least two different particle sizes. The hemispherical shape of each particle can either be made by immersing a spherical particle into the flat glass sheet to a certain depth, or can be hemispherical particles disposed on the surface of the flat glass sheet, for example.

The inorganic substrate, in one embodiment, comprises a material selected from a glass, a ceramic, a glass ceramic, sapphire, silicon carbide, a semiconductor, and combinations thereof.

The inorganic particles can comprise a material selected from a glass, a ceramic, a glass ceramic, sapphire, silicon carbide, a semiconductor, metal oxides, and combinations thereof.

In one embodiment, a first portion of the hemispherical particles have an average diameter of 500 nm or less and wherein a second portion of the hemispherical particles have an average diameter of 500 nm or more.

According to one embodiment, the first portion of the particles has an average diameter in the range of from 200 nm to 300 nm.

According to one embodiment, the second portion of the particles has an average diameter in the range of from 1 micron to 3 microns.

According to one embodiment, the particles are distributed in a monolayer. The particles may be distributed in a pattern, for example, a repeating square or hexagonal pattern.

One embodiment, features of which are shown in FIG. 11, is a photovoltaic device 1100 comprising the light scattering inorganic substrate 10 according to embodiments disclosed herein. The photovoltaic device, according to one embodiment further comprises a conductive material 24 adjacent to the substrate, and an active photovoltaic medium 22 adjacent to the conductive material.

The active photovoltaic medium, according to one embodiment, is in physical contact with the conductive material. The conductive material, according to one embodiment is a transparent conductive film, for example, a transparent conductive oxide (TCO). The transparent conductive film can comprise a textured surface. The TCO can be a conformal film.

The photovoltaic device, in one embodiment, further comprises a counter electrode 26 in physical contact with the active photovoltaic medium and located on an opposite surface of the active photovoltaic medium as the conductive material.

The counter electrode can comprise a textured surface. The counter electrode can be a conformal layer.

The active photovoltaic medium can comprise multiple layers. In one embodiment, the active photovoltaic medium comprises amorphous silicon, microcrystalline silicon, or a combination thereof. According to one embodiment, the active photovoltaic medium comprises cadmium telluride or copper indium gallium diselenide (CIGS). The photovoltaic cell can be a silicon tandem junction or silicon multi-junction cell.

The active photovoltaic medium can comprise a textured surface or when the medium comprises multiple layers, each layer can comprise a textured surface. The active photovoltaic medium can be a conformal layer.

The TCO, active photovoltaic medium, and counter electrode can be manufactured as is known in the art to manufacture a photovoltaic device.

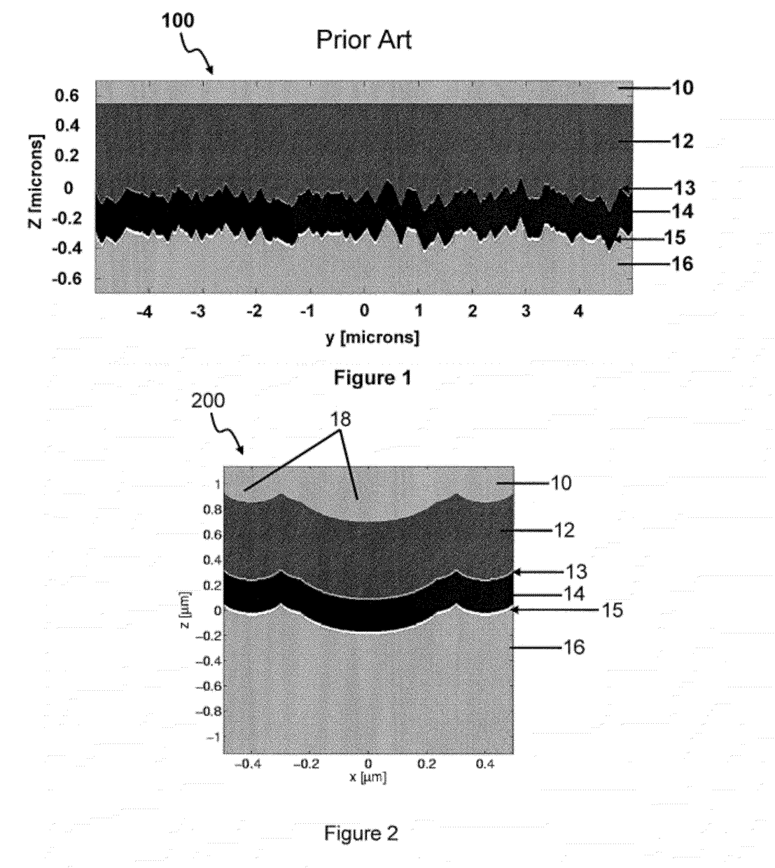

A cross-section of the three-dimensional geometry of features of a typical amorphous silicon (a-Si) cell 100 based on a flat glass substrate 10 is shown in FIG. 1. The cell has a transparent conductive oxide (TCO) layer 12, for example, zinc oxide (ZnO) disposed on the flat glass substrate; a p a-Si, i a-Si, n a-Si (pin) junction (13, 14, 15, respectively); and a back-reflector 16 such as aluminum (Al). The RMS of the roughness of the TCO layer is 35 nm, maximum roughness height is 200 nm, and the correlation radius is 140 nm, with a Gaussian correlation function.

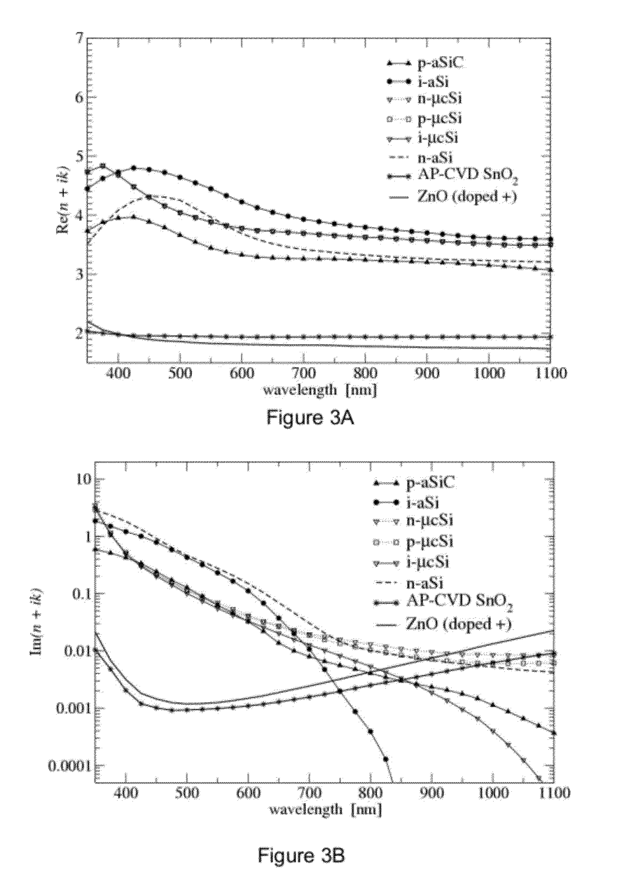

FIG. 2 shows the corresponding geometry of amorphous silicon (a-Si) cell 200 based on a light scattering inorganic substrate 10, formed by hemispherical glass particles 18 of different sizes distributed on a flat glass surface, according to one embodiment. The cell comprises a transparent conductive oxide (TCO) layer 12, for example, zinc oxide (ZnO) (600 nm average thickness) disposed on the flat glass substrate; a p a-Si (10 nm average thickness), i a-Si (250 nm average thickness), n a-Si (20 nm average thickness) pin junction (13, 14, 15, respectively); and a back-reflector 16 such as aluminum (Al). The TCO and all subsequent layers are conformal to the texture provided by the particles on the glass surface. All simulated a-Si cells have the same material optical constants, as shown in FIG. 3A and FIG. 3B, and layer thicknesses as the flat glass substrate cell used for comparison. For simulations, a full vectorial, three dimensional (3D) Finite-Difference Time-Domain (FDTD) approach was used. The FDTD method directly solves Maxwell's equations in the time domain without any simplifying assumptions and is regarded as one of the most reliable and accurate numerical methods. Since the 3D problem requires a significant Central Processing Unit (CPU) time, the task was parallelized on 32-64 processors of the multi-processor cluster. In FDTD simulations, the optical absorption efficiency of the cell is evaluated by directly computing the integral of the divergence of the Poynting vector (<div S>) over the volume of the intrinsic a-Si absorbing layer. FIG. 3A shows the real part of the complex-valued optical constant. FIG. 3B shows the imaginary part of the optical constant. Glass is assumed to have negligible absorption and spectrally flat index n=1.5 at the wavelengths of interest.

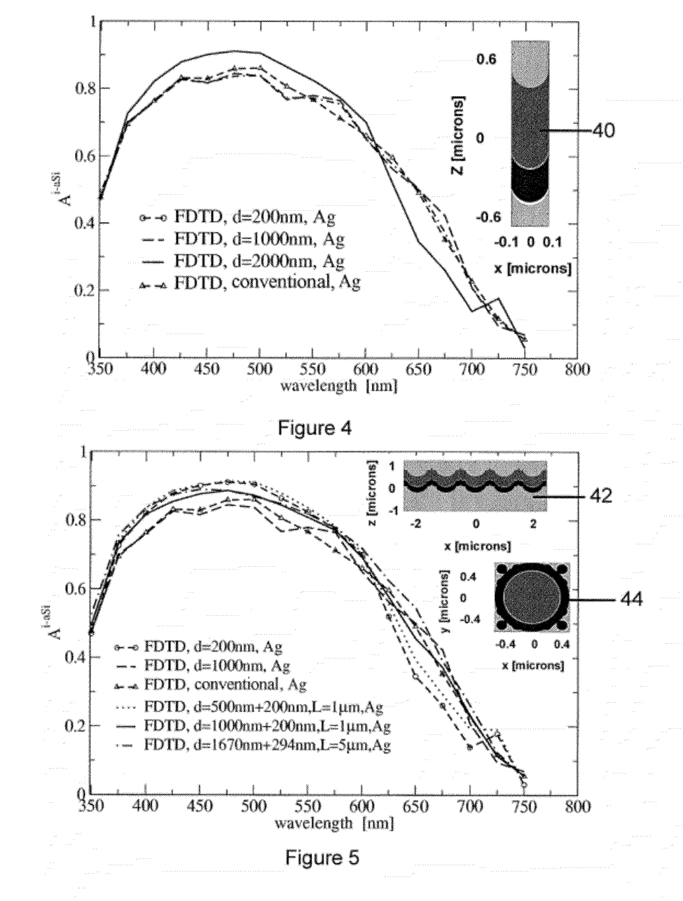

FIG. 4 shows the absorption efficiency (normalized to the energy flux incident from the glass) for conventional flat glass substrate based cells (solid curve) from FIG. 1 and for light scattering inorganic substrate base cells (dashed curves) with periodic distributions of d=200 nm-2000 nm diameter hemispherical particles. The cells used silver back-reflectors. The inset 40 shows a sample xy cross-section of the unit lattice-element of a cell with 200 nm diameter particles. In FIG. 4, the absorption efficiency (normalized to the energy flux incident from the glass) for conventional flat substrate based cells and for a light scattering inorganic substrate based cells comprising particles of different sizes, small (200 nm) and large (1-2 μm) hemispherical particles distributed on a planar glass surface, according to one embodiment. In light scattering inorganic substrate based cells with only small particle diameters the optical absorption is higher by 5-10% for the wavelength band 400-600 nm, but is lower than the efficiency of the conventional flat glass based cells at longer wavelengths. The absorption efficiency of light scattering inorganic substrate based cells with 1 μm or 2 μm particle diameter is enhanced at longer wavelengths, compared to the case of 200 nm particles, while being comparable to the conventional flat glass cell efficiency at shorter wavelengths. The label “Ag” in the figure legend refers to silver back-reflector assumed in simulations.

Combining the absorption enhancement due to small d=200 nm particles at short wavelengths with the enhancement exhibited by d=1-2 μm particles at long wavelengths, leads to improved absorption for all wavelengths as shown in FIG. 5 (cf. dashed and solid curves). To calculate the maximum achievable current density (MACD), the QE was weighted with the standard solar reference spectrum I_{AM1.5}:

$$MACD = \frac{q}{hc} {\int }_{Λ} QE ( λ ) {I}_{AM 1.5} ( λ ) λ d λ$$

wherein q is the electron charge, h is the Planck's constant, c is the speed of light, λ is the light wavelength, and Λ is the solar spectrum wavelength domain. Several configurations have been tested to identify an optimum size of both particle groups, with surfaces textured by d=1.67 μm and d=0.294 μm particles leading to ˜7% improvement in the MACD, compared to the conventional flat glass cell with a rough TCO.

FIG. 5 shows the absorption efficiency computed for the conventional flat glass substrate cells (solid curve with triangles) and for light scattering inorganic substrate based cells comprising particles of different sizes with periodic distributions of hemi-spherical particles. For combined particle distributions, “L” denotes the unit lattice-element size. The top inset 42 shows a sample xz cross-section of a cell deposited on a glass surface textured by a combination of 200 nm and 1000 nm diameter particles, embedded in a unit lattice-element of size 1 μm. The bottom inset 44 shows the corresponding xy cross-section of the unit lattice-element of that periodic distribution.

The combined particle distributions are obtained by first populating the glass surface by a single layer of small hemi-spherical particles, arranged in a square lattice. Then the larger particle is inserted, by replacing the smaller ones in the regions of overlap. Depending on the particle to the lattice period ratio, an enhancement in the absorption can be realized for nearly all wavelengths (FDTD, d=1000 nm+200 nm, L=1 μm, Ag curve) with varying degree of trade-off at short and long wavelengths.

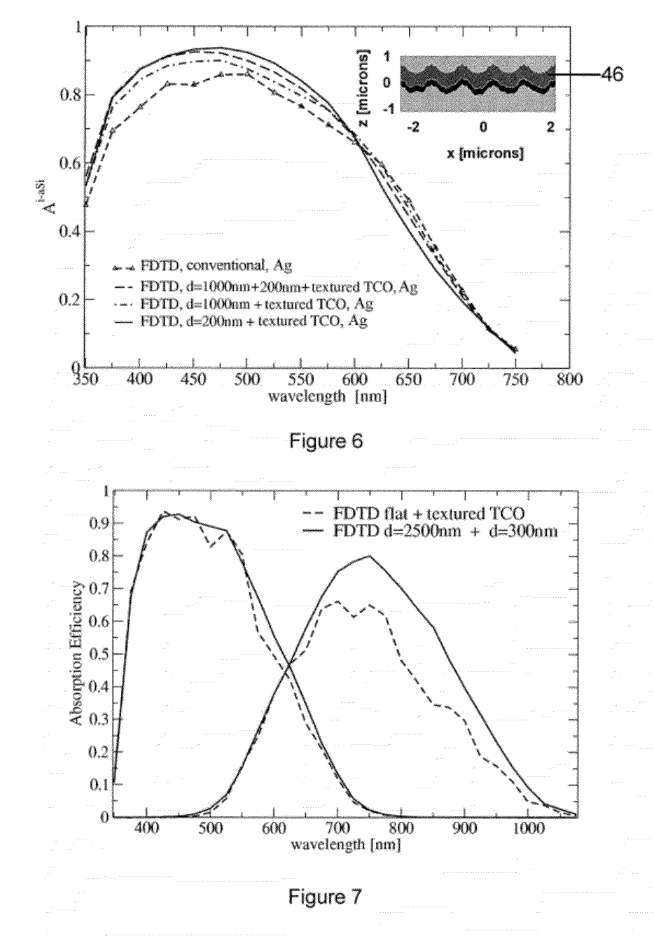

FIG. 6 shows absorption efficiency computed for a conventional a-Si cell based on a flat glass substrate and for light scattering inorganic substrate based cells with periodic distributions of smooth hemispherical particles at the glass/TCO interface and rough TCO/a-Si interface. Absorption in the cells with combined 1 μm and 200 nm hemispherical particles at the glass/TCO interface and a conventional rough TCO at the TCO/a-Si interface (FIG. 6) shows a similar result: improvement at long wavelengths, compared to the mono-disperse d=200 nm particle distribution, and an improvement at short wavelengths, compared to the mono-disperse d=1 μm particle case. The improvement in the MACD of the combined 200 nm and 1 μm multi-particle cells with rough TCO was found to be ˜4.5%, when compared to the conventional a-Si cell based on a flat glass substrate with rough TCO. The observed effect can be explained by increased transmission of light from the glass side, accompanied by increased reflectivity from the silicon side (AR-HR effect). The inset 46 shows a sample xz cross-section of a cell deposited on a glass surface textured by a combination of 200 nm diameter particles, embedded in a unit lattice-element of size 1 μm.

Absorption efficiency is enhanced at short wavelengths for particles with d>100 nm. The maximum enhancement occurs for 200 nm diameter particles between λ=400 nm and 600 nm, and there is a tendency for larger particles to lead to larger absorption at long wavelengths, λ>650 nm.

FIG. 7 shows the absorption efficiency dependence on the wavelength computed for a tandem cell, according to one embodiment. Absorption efficiency of silicon tandem (a-Si/uc-Si) cells deposited on a flat glass substrate with a textured TCO and on a light scattering inorganic substrate comprising hemispherical bumps of diameter d=2500 nm and height 800 nm, arranged on a hexagonal lattice, and combined with a smaller hemispherical particles of diameter 300 nm, arranged on a square lattice. The small size (d=300 nm) particles improve absorption efficiency at short wavelengths (<600 nm) to the level comparable to that of the flat glass+textured TCO cells, while the large particle texture (d=2500 nm) results in improved efficiency at wavelengths >600 nm.

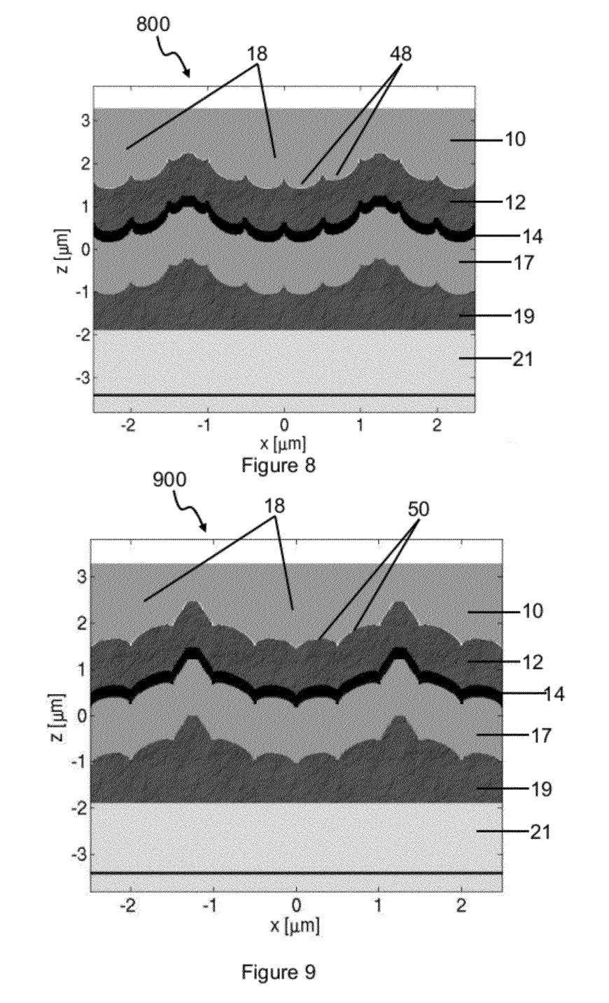

FIG. 8 is a cross-section of a unit lattice-element of a periodic Si-tandem cell 800 based on a light scattering inorganic substrate comprising a combination of large diameter glass particles 18; and convex areas 48 distributed on the surface of the particles 18, on a planar glass sheet 10, according to one embodiment. Features 12 and 14 are as previously described. A uc-Si layer 17 is adjacent to an a-Si layer 14. A second TCO layer 19 (back-TCO) is adjacent to uc-Si layer 17 and can be the same or a different material material as TCO 12. Back reflector layers 21 (such as volumetric scattering layers) are adjacent to the second TCO layer 19.

FIG. 9 is a cross-section of a unit lattice-element of a periodic Si-tandem cell 900 based on a light scattering inorganic substrate comprising a combination of large diameter glass particles 18; and concave areas 50 distributed on the surface of the particles 18, on a planar glass sheet 10, according to one embodiment. Features 12 and 14 are as previously described. A uc-Si layer 17 is adjacent to an a-Si layer 14. A second TCO layer 19 (back-TCO) is adjacent to uc-Si layer 17 and can be the same or a different material material as TCO 12. Back reflector layers 21 (such as volumetric scattering layers) are adjacent to the second TCO layer 19.

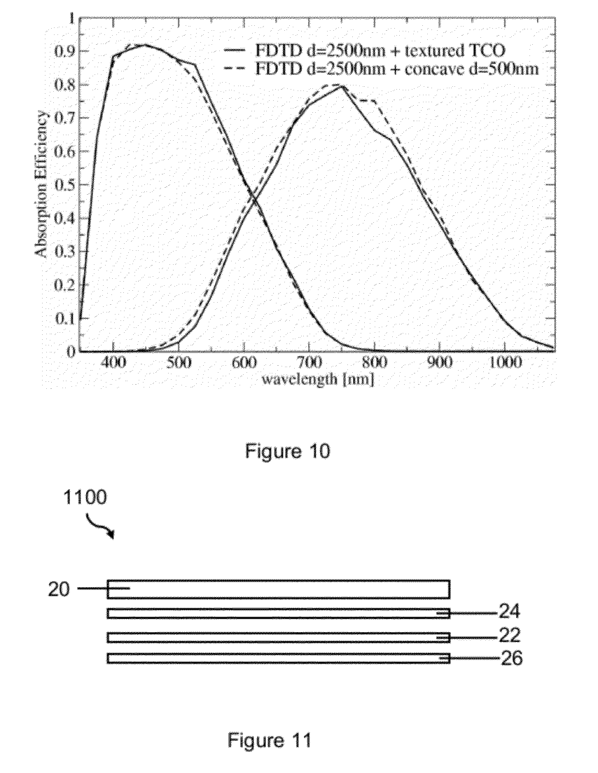

FIG. 10 is a graph of the comparison of absorption efficiency of silicon tandem cells deposited on a light scattering inorganic substrate comprising hemispherical bumps of diameter d=2500 nm and height 800 nm, arranged on a hexagonal lattice, and of the same type of substrate but with additional texture formed by smaller size d=500 nm etched (concave) hemispherical features.

What is claimed is:

1. A light scattering inorganic substrate comprising an inorganic sheet having composite features distributed on a surface of the inorganic sheet, wherein the composite features each comprise at least a first and a second size scale, wherein the first size scale enhances light absorption at wavelengths in the range of from 350 nm to 600 nm, and wherein the second size scale enhances light absorption at wavelengths in the range of from 600 nm to 1100 nm.

2. The substrate according to claim 1, wherein the first size scale is smaller than the second size scale.

3. The substrate according to claim 1, wherein the composite features each comprise at least two different sized inorganic particles.

4. The substrate according to claim 3, wherein the particles are spherical and a portion of each of the particles protrudes from the surface.

5. The substrate according to claim 4, wherein each particle protrudes from the surface at a height of from the particle diameter divided by 4 to a height of the particle diameter divided by 2.

6. The substrate according to claim 2, wherein the particles comprise a material selected from a glass, a ceramic, a glass ceramic, sapphire, silicon carbide, a semiconductor, metal oxides, and combinations thereof.

7. The substrate according to claim 1, wherein the composite features each comprise an inorganic particle having the second size scale; and concave areas distributed on a surface of the particle and having the first size scale.

8. The substrate according to claim 1, wherein the composite features each comprise an inorganic particle having the second size scale; and convex areas distributed on a surface of the particle and having the first size scale.

9. The substrate according to claim 1, wherein the inorganic sheet is planar.

10. The substrate according to claim 9, wherein the planar inorganic sheet comprises a material selected from a glass, a ceramic, a glass ceramic, sapphire, silicon carbide, a semiconductor, and combinations thereof.

11. The substrate according to claim 1, wherein the second size scale is in the range of from greater than 600 nm to 8 microns.

12. The substrate according to claim 1, wherein the first size scale is in the range of from 600 nm or less.

13. The substrate according to claim 12, wherein the first size scale is in the range of from 1 nm to 600 nm.

14. The substrate according to claim 1, wherein the composite features are distributed in a monolayer.

15. The substrate according to claim 1, wherein the composite features are distributed in a pattern.

16. A photovoltaic device comprising the light scattering inorganic substrate according to claim 1.

17. The device according to claim 16, further comprising
a conductive material adjacent to the substrate; and
an active photovoltaic medium adjacent to the conductive material.

18. The device according to claim 17, wherein the conductive material is a transparent conductive film.

19. The device according to claim 18, wherein the transparent conductive film comprises a textured surface.

20. The device according to claim 17, wherein the active photovoltaic medium is in physical contact with the transparent conductive film.

21. The device according to claim 17, further comprising a counter electrode in physical contact with the active photovoltaic medium and located on an opposite surface of the active photovoltaic medium as the conductive material.
